(19) United States
(12) Patent Application Publication
(10) Pub. No.: US 2005/0174745 A1
(43) Pub. Date: Aug. 11, 2005

(54) Electronic assembly

(76) Inventors: Michael Higgins, Monmouthshire (GB); Tom Collins, Caerphilly (GB); Martin McHugh, Newport (GB)

Correspondence Address: ARENT FOX PLLC, 1050 CONNECTICUT AVENUE, N.W., SUITE 400, WASHINGTON, DC, 20036, US

(21) Appl. No.: 11/030,163

(22) Filed: Jan. 7, 2005

(30) Foreign Application Priority Data
Jan. 9, 2004 (GB) 0400363.8

(51) Int. Cl. H05K 1/16

(52) U.S. Cl. 361/765; 361/777

(57) ABSTRACT

An electronic assembly (30) comprises a substrate element (32) having a mounting surface (34), circuitry (38) disposed on the mounting surface (34), an edge surface (36) at the periphery of and distinct from the mounting surface (34), and an electrically-conductive track (40) extending from the circuitry (38) along at least part of the edge surface (36) to form at least one electronic component. The conductive track (40) can be used to form an electronic component such as antenna, an inductor or a resistor, and results in a highly efficient use of the available substrate surface area.

### BACKGROUND OF THE INVENTION

1. Field of the Invention

The present invention relates to an electronic assembly comprising a substrate element having a mounting surface, circuitry disposed on the mounting surface, and an edge surface distinct from the mounting surface.

2. Description of the Related Art

FIG. 1 of the accompanying drawings is a schematic illustration of an electronic assembly 2 for use in a radio frequency communication link. The electronic assembly 2 comprises a substrate element 4 having a mounting surface 6 on which is disposed circuitry for performing the radio frequency communication function of the electronic assembly 2. An alumina substrate is often used for the substrate element 4, and the circuitry in FIG. 1 comprises various passive components 10 such as resistors and capacitors, and these passive components are usually printed directly onto the mounting surface 6 of the substrate element 4 using a so-called thick film process. Various active components such as an integrated circuit (IC) 12 and a transistor 8 are attached to the mounting surface 6 with conductive epoxy, wire bonding or soldering. The alumina substrate element 4 is typically 0.5 to 1 mm thick, although other thicknesses are readily available. The various active and passive components in the circuitry are interconnected using a printed conductive track 16 usually applied by the thick film printing process; an etching (“thin film”) process or mechanical erosion (e.g. by sand blasting, milling etc.) of pre-coated substrates could also be used. Connections from the IC 12 to the printed track 16 are formed by way of bond wire 14.

The electronic assembly 2 also comprises an external antenna 18 that is connected to the circuitry disposed on the mounting surface 6 of the substrate element 4 with a cable 22 and connector 20.

For many applications, the circuitry disposed on the substrate element 4 can be made to be very small, but the circuitry can be dwarfed by the size of the antenna 16. Thus the antenna becomes the largest part of the radio frequency communication link. Furthermore, the cable 22 and connector 20 are bulky and expensive.

It is therefore desirable to minimise the volume occupied by the radio frequency communication circuitry including the antenna. This is particularly true for short-range applications such as mobile phones, pagers and medical applications.

Instead of using an external antenna 18 such as that shown in FIG. 1, it has been previously considered to print an antenna directly onto the mounting surface 6 of the substrate element 4 (or alternatively, a printed circuit board). Although this is an improvement upon using a bulky external antenna, a substantial area of the mounting surface 6 is still occupied by the printed antenna, and this therefore increases the cost and reduces the manufacturing efficiency. For example, a loop antenna can be fabricated where the effectiveness of the loop antenna is increased with the number of turns in the loop. The larger the loop, within certain restrictions, the better the performance of the antenna. This can produce an efficient antenna in a small area, but the antenna still occupies valuable area on the mounting surface of the substrate element (or printed circuit board).

It is therefore desirable to provide an electronic assembly in which the above-mentioned disadvantages are overcome.

U.S. Pat. No. 4,577,195 discloses a miniaturized mobile radio receiver having two printed circuit boards disposed in a housing, with a wire portion on each printed circuit board forming two halves of a dipole antenna. The base of the antenna is located on either printed circuit board. The wires are disposed on the main face of their respective printed circuit boards towards the periphery of the board.

Each of GB-A-2248345, JP-A-11274669, U.S. Pat. No. 4,539,747 and U.S. Pat. No. 3,398,232 can be considered to disclose an electronic assembly having a conductive track extending from circuitry on a mounting surface onto and along an edge surface surrounding the mounting surface, for various different purposes. In GB-A-2248345, the conductive tracks on the edge surface are electroplated channels, which are concave shaped to partially embrace wire leads extending vertically downward from a display board placed on top of the printed circuit board, which are then soldered to the electroplated channels. In JP-A-11274669, the conductive track is an edge circuit which is provided for heat dissipation purposes. In U.S. Pat. No. 4,539,747, the conductive tracks are conductive “ribs” which are provided as an electrical connection between two surfaces of a printed circuit board. In U.S. Pat. No. 3,398,232, the conductive tracks are provided for the same purpose as those in U.S. Pat. No. 4,539,747.

### SUMMARY OF THE INVENTION

An embodiment of one aspect of the present invention provides an electronic assembly comprising a substrate element having a mounting surface. Circuitry is disposed on the mounting surface. An edge surface is at the periphery of and distinct from the mounting surface. An electrically-conductive track extends from the circuitry along at least part of the edge surface to form at least one electronic component.

The mounting surface may be substantially planar.

The edge surface may form an angle with the mounting surface where the surfaces meet.

The edge surface may be substantially normal to the mounting surface where the surfaces meet.

The conductive track may extend along the edge surface in a direction substantially parallel to the nearby mounting surface.

The substrate element may be substantially cuboidal, with one surface of the cuboid forming the mounting surface and the four side surfaces of the cuboid adjacent the, mounting surface collectively forming the edge surface. The conductive track may extend along at least two of the four side surfaces. The conductive track may extend along at least three of the four side surfaces. The conductive track may extend along all of the four side surfaces.

The conductive track may form at least one complete turn around the edge surface.

The conductive track may form a number of turns around the edge surface in a helical shape.

The substrate element may be uniformly formed of a non-conductive material. The non-conductive material may be alumina.

The substrate element may be a printed circuit board.

The substrate element may be a semiconductor wafer.

At least part of the circuitry may be formed on the substrate element by a thick film printing process.

The conductive track may be arranged to form an antenna. The circuitry may comprise a radio frequency electronic component. The conductive track may be arranged to form a helical antenna as one or more of the at least one electronic components.

The conductive track may be open-ended.

Alternatively the conductive track may extend from the edge surface back to the mounting surface to form a closed loop. The conductive track may extend back to the circuitry using a via hole through the substrate element.

The conductive track may be arranged so as not to intersect itself.

The conductive track may extend back to the circuitry using a return path extending over or under the outward path conductive track, with an electrically-insulating layer in between.

The conductive track may be arranged to form an inductive element as one or more of the at least one electronic components.

The conductive track may be arranged to form a resistive element as one or more of the at least one electronic components.

The conductive track may be formed by a thick film printing process.

The substrate element may be thin or wafer-like so that the edge of the substrate element forms the edge surface. A lateral dimension of the mounting surface may be at least 30 times the thickness of the substrate element. A lateral dimension of the mounting surface may be at least 60 times the thickness of the substrate element.

### BRIEF DESCRIPTION OF THE DRAWINGS

FIG. 1, discussed hereinbefore, is a schematic diagram showing a previously-considered electronic assembly including an antenna;

FIG. 2 is a schematic diagram showing an electronic assembly according to an embodiment of the present invention;

FIG. 3 is a schematic diagram showing one possible way of forming a return path in a closed-loop embodiment of the present invention; and

FIG. 4 is a schematic diagram showing another way of forming a return path in a closed-loop embodiment of the present invention.

### DETAILED DESCRIPTION OF THE PREFERRED EMBODIMENTS

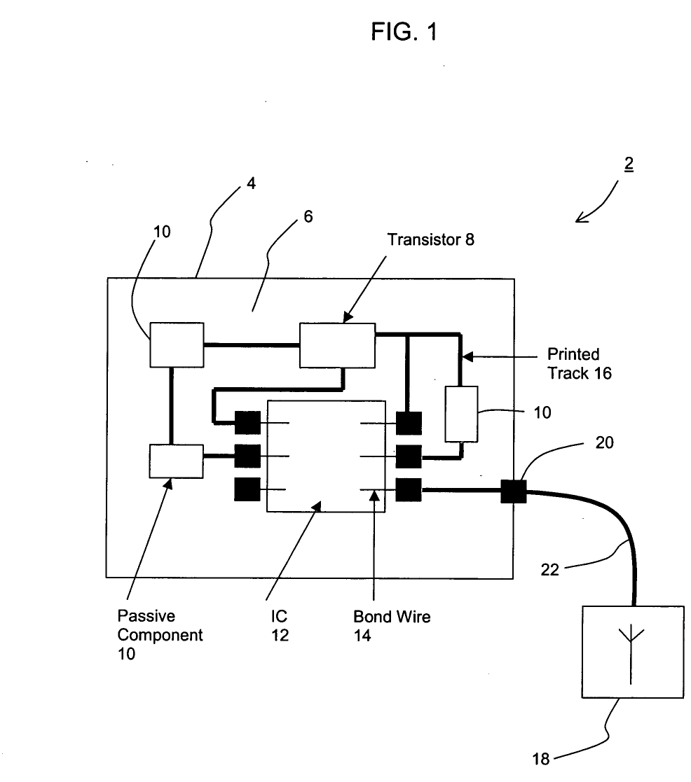

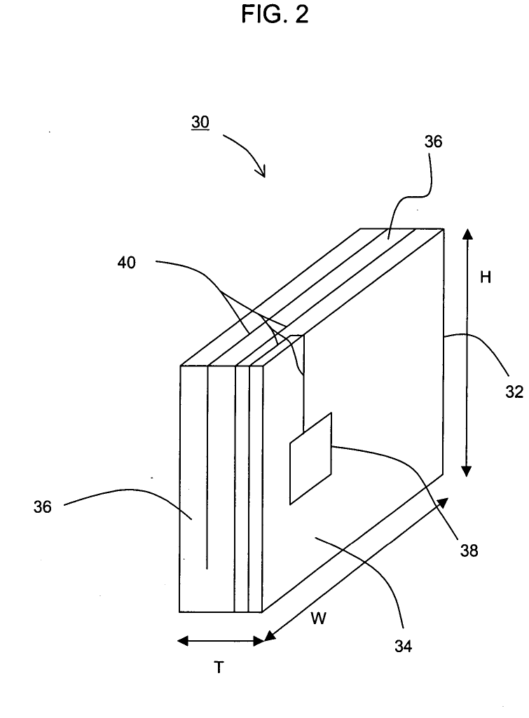

FIG. 2 is a schematic diagram showing an electronic assembly 30 according to a first embodiment of the present invention. The electronic assembly 30 comprises a substrate element 32 having a mounting surface 34 and an edge surface 36. The substrate element 32 is substantially cuboidal, with one surface of the cuboid forming the mounting surface 34 and the four side surfaces of the cuboid adjacent the mounting surface 34 collectively forming the edge surface 36. The substrate element is formed from alumina. Circuitry 38 is disposed on the mounting surface 34. The circuitry 38 comprises various radio frequency and other electronic components, for example corresponding to those components other than the antenna component 18 described above with reference to FIG. 1.

Unlike the previously-considered electronic assemblies described above, where the antenna component 18 is either provided as a separate item (usually bulky) or printed on the mounting surface of the substrate, in an embodiment of the present invention the edge surface 36 of the substrate 32 is employed for this purpose. As shown in FIG. 2, the first embodiment of the present invention comprises an electrically-conductive track 40 which extends from the circuitry 38 along the mounting surface 34 to the edge surface 36. The conductive track 40, which is applied by a thick film printing process, is made to extend around the edge surface 36 to form a number of turns in a helical shape. The conductive track 40 is therefore arranged as a helical antenna, which is shown in FIG. 2 as an open-ended helical antenna. The greater the number of turns, the greater the effectiveness of the helical antenna. The maximum number of turns of the loop is defined by the accuracy of the thick film printing process.

Thick film printing uses ink that is hard when cured and is a good electrical conductor, and gold is one example of the electrically-conducting material that can be used. The ink is applied through a fine mesh with the area to be printed being defined by a pattern on the mesh. Once applied, the alumina substrate element 32 is heated to a predetermined temperature for a specific period of time, and this causes the ink to solidify and form a solid conductive track. The thick film printing process will be well known to those familiar with the art.

In one particular embodiment, the electronic assembly 30 is arranged to provide a 400 MHz transmitter. The alumina substrate element 32 has a width W of 3 cm, a height H of 3 cm and a thickness T of 1 mm. With these dimensions, the thick film printing process used can allow the formation of about two turns of gold conductive track 40 printed on the edge surface 36 of the substrate 32.

The use of the edge surface 36 of the substrate element 32 results in a highly efficient use of available substrate area, and frees up the valuable and limited area on the mounting surface 34 of the substrate 32 as compared to the previously-considered scheme of printing a patch antenna onto the mounting surface 34. The overall size of the electronic assembly 30 is also much reduced as compared to the previously-considered scheme where a separate and bulky antenna element is employed.

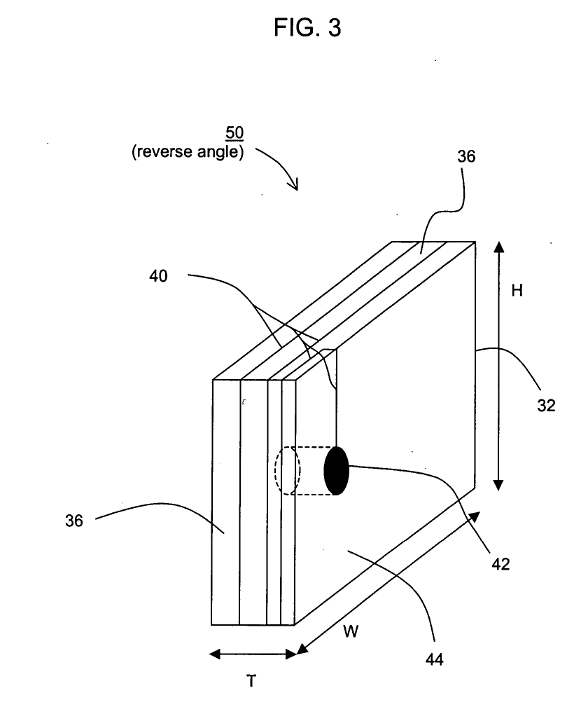

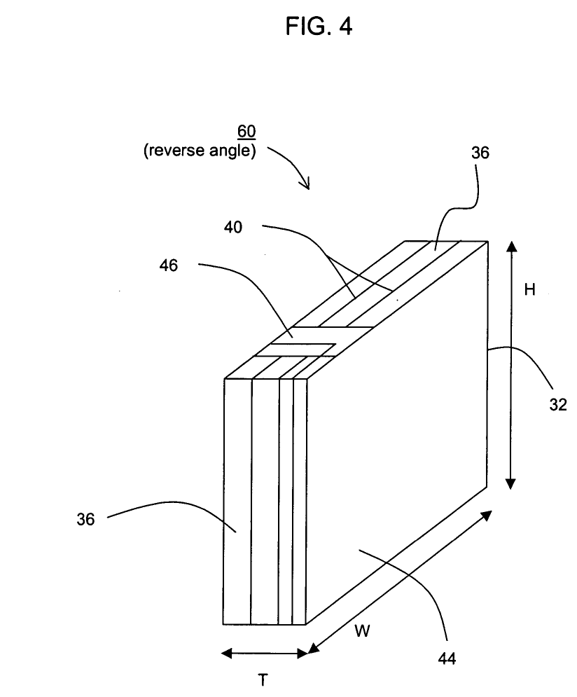

The embodiment described above with reference to FIG. 2 is an open-ended antenna. It is also possible to form a closed-loop antenna on the edge surface of the substrate, and two such embodiments will now be described with reference to FIGS. 3 and 4.

FIG. 3 is a schematic diagram showing an electronic assembly 50 according to a second embodiment which is similar to the electronic assembly 30 described above with reference to FIG. 2, but in FIG. 3 the reverse angle is shown so that the visible surface is the back surface 44 rather than the mounting surface 34. In the second embodiment, the conductive track 40 extends from the mounting surface 34 around the edge surface 36 in a number of turns, eventually reaching the back surface 44. The conductive track 40 extends a short distance along the back surface 44 where it connects electrically with a conductive via hole extending through the substrate 32 to form a connection to the mounting surface 34. In this way, a closed-loop antenna can be formed.

FIG. 4 is a schematic diagram showing an electronic assembly 60 according to a third embodiment of the present invention, which is generally similar to the second embodiment described above with reference to FIG. 3. However, instead of the return part of the conductive track being formed as a conductive via hole 42 through the substrate element 32, in the third embodiment an electrically-insulating layer 46 is printed over part or all of the already-formed conductive track to allow a return track to be printed over the top of this layer 46 to reach the mounting surface 34. In this way, a closed-loop antenna can be formed.

Although the above embodiments show a substrate element 32 which is substantially cuboidal and has a substantially rectangular or square mounting surface 34, it will be appreciated that any shaped substrate element can be used, for example a circular substrate. Similarly, although the mounting surface 34 in the above embodiment is substantially planar, this is not essential. In the above embodiments, the edge surface 36 is distinct from the mounting surface 34 in that the two surfaces meet at an angle. Although it will usually be the case that the edge surface 36 is substantially normal to the mounting surface 34 where the surfaces meet, it will be appreciated that this is not essential. It is also preferred, but not essential, that the conductive track 40 extends along the edge surface 36 in a direction substantially parallel to the nearby mounting surface 34; other shapes of conductive track will also serve the function.

Although the preferred embodiments have a helical antenna arrangement, any other type of antenna shape can be formed on the edge surface 36. For example a dipole, coil, fractal or whip antenna shape is also possible. In addition, an electronic assembly embodying the present invention may be used with or without a ground plane.

An alternative to printing onto an alumina substrate element is to start with an alumina substrate element coated with conductor and then etch away unwanted conductor. This is known as the thin film process. Copper, gold, silver, nicrome alloy or other types of conductor can be used in such a process. The substrate element can be coated on any number of available sides.

Printed circuit board (PCB) is a common medium for electronic and radio frequency circuits, and the substrate element 36 can be of this type instead of being an alumina substrate. An etching process is usually used with printed circuit boards. Other types of substrate include ferrite, Duroid (trademark), glass, alumina with various impurities, or any other type of insulating material. The substrate element may also be formed from a semiconductor material.

The main application of an edge-printed conductive track described above is for use as an antenna. However, it will be appreciated that the edge-printed track can be used in a corresponding manner to form other types of electronic component such as an inductor or a resistor. Tracking merely for the purpose of providing an electrical connection between two circuitries is not considered to be an “electronic component”. A power resistor would provide a particularly good application as the heat dissipation would be high. The edge-printed track could be used to form a heater, for example in temperature-controlled applications. Use as an inductor would be particularly advantageous where a large area is needed, such as for a position sensor. Another potential application would be for use in a delay line. A track disposed on an edge surface could be used to perform numerous other functions.

It will be appreciated that, if both the back surface 44 and the mounting surface 34 have circuitry disposed thereon, it would not be necessary to provide a return path for the conductive track. Instead, the conductive track 40 would form a connection between the circuitry on the mounting surface 34 and the circuitry on the back surface 44.

1. An electronic assembly comprising a substrate element having a mounting surface, circuitry disposed on the mounting surface, an edge surface at the periphery of and distinct from the mounting surface, and an electrically-conductive track extending from the circuitry along at least part of the edge surface to form at least one electronic component.

2. An electronic assembly as claimed in claim 1, wherein the mounting surface is substantially planar.

3. An electronic assembly as claimed in claim 1, wherein the edge surface forms an angle with the mounting surface where the surfaces meet.

4. An electronic assembly as claimed in claim 1, wherein the edge surface is substantially normal to the mounting surface where the surfaces meet.

5. An electronic assembly as claimed in claim 1, wherein the conductive track extends along the edge surface in a direction substantially parallel to the nearby mounting surface.

6. An electronic assembly as claimed in claim 1, wherein the substrate element is substantially cuboidal, with one surface of the cuboid forming the mounting surface and the four side surfaces of the cuboid adjacent the mounting surface collectively forming the edge surface.

7. An electronic assembly as claimed in claim 6, wherein the conductive track extends along at least two of the four side surfaces.

8. An electronic assembly as claimed in claim 7, wherein the conductive track extends along at least three of the four side surfaces.

9. An electronic assembly as claimed in claim 8, wherein the conductive track extends along all of the four side surfaces.

10. An electronic assembly as claimed in claim 1, wherein the conductive track forms at least one complete turn around the edge surface.

11. An electronic assembly as claimed in claim 1, wherein the conductive track forms a number of turns around the edge surface in a helical shape.

12. An electronic assembly as claimed in claim 1, wherein the substrate element is uniformly formed of a non-conductive material.

13. An electronic assembly as claimed in claim 12, wherein the non-conductive material is alumina.

14. An electronic assembly as claimed in claim 1, wherein the substrate element is a printed circuit board.

15. An electronic assembly as claimed in claim 1, wherein the substrate element is a semiconductor wafer.

16. An electronic assembly as claimed in claim 1, wherein at least part of the circuitry is formed on the substrate element by a thick film printing process.

17. An electronic assembly as claimed in claim 1, wherein the conductive track is arranged to form an antenna on the edge surface.

18. An electronic assembly as claimed in claim 17, wherein the circuitry comprises a radio frequency electronic component.

19. An electronic assembly as claimed in claim 17, wherein the conductive track forms a number of turns around the edge surface in a helical shape to form a helical antenna on the edge surface.

20. An electronic assembly as claimed in claim 1, wherein the conductive track is open-ended.

21. An electronic assembly as claimed in claim 1, wherein the conductive track extends from the edge surface back to the mounting surface to form a closed loop.

22. An electronic assembly as claimed in claim 21, wherein the conductive track extends back to the circuitry using a via hole through the substrate element.

23. An electronic assembly as claimed in claim 1, wherein the conductive track is arranged so as not to intersect itself.

24. An electronic assembly as claimed in claim 21, wherein the conductive track extends back to the circuitry using a return path extending over or under the outward path conductive track, with an electrically-insulating layer in between.

25. An electronic assembly as claimed in claim 1, wherein the conductive track is arranged to form an inductive element.

26. An electronic assembly as claimed in claim 1, wherein the conductive track is arranged to form a resistive element.

27. An electronic assembly as claimed in claim 1, wherein the conductive track is formed by a thick film printing process.

28. An electronic assembly as claimed in claim 1, wherein the substrate element is thin or wafer-like so that the edge of the substrate element forms the edge surface.

29. An electronic assembly as claimed in claim 28, wherein a lateral dimension of the mounting surface is at least 30 times the thickness of the substrate element.

30. An electronic assembly as claimed in claim 29, wherein a lateral dimension of the mounting surface is at least 60 times the thickness of the substrate element.
